(19) United States
(12) Patent Application Publication
(10) Pub. No.: US 2018/0019352 A1
(43) Pub. Date: Jan. 18, 2018

(54) PHOTOVOLTAIC CELL AND ASSOCIATED LAYOUT

(71) Applicant: THALES, COURBEVOIE (FR)

(72) Inventors: Laurent D'ABRIGEON, CALLIAN (FR); Bernard BOULANGER, FREJUS (FR)

(21) Appl. No.: 15/642,243

(22) Filed: Jul. 5, 2017

(30) Foreign Application Priority Data
Jul. 12, 2016 (FR) 1601087

(51) Int. Cl. H01L 31/0352; H01L 31/0443

(52) U.S. Cl. CPC H01L 31/035281; H01L 31/0443

(57) ABSTRACT

A network of photovoltaic cells that are aligned in at least one row wherein, in one row of cells, the base of a cell is alternately on one edge of the row then on the other edge of the row, the photovoltaic cells being the shape of a half regular hexagon the environs of the vertices of which are truncated so that the truncation corresponds to a section of a semicircle the base and diameter of which is superposed and centred on the base of the half-hexagon, the base of the half-hexagon being comprised between 1 and

$$\frac{2}{\sqrt{3}}$$

times the diameter of the semicircle.

### CROSS-REFERENCE TO RELATED APPLICATIONS

This application claims priority to foreign French patent application No. FR 1601087, filed on Jul. 12, 2016, the disclosure of which is incorporated by reference in its entirety.

### FIELD OF THE INVENTION

The invention relates to a photovoltaic cell and to an associated layout.

The present invention relates to photovoltaic electrical networks and cells.

### BACKGROUND

A photovoltaic cell, also called a solar cell, is an electronic component that, exposed to light (photons), produces electricity via the photovoltaic effect.

The electrical power obtained is proportional to the radiant power incident on the photovoltaic cell and to the area of the cell.

The most used photovoltaic cells are based on semiconductors, and mainly based on gallium arsenide (GaAs).

Photovoltaic cells are produced on a substrate or wafer, i.e. a crystal structure that is originally circular but then cut to the desired geometry, this structure also being referred to as a raw cell.

The photovoltaic cells are then equipped with interconnectors; covered with a cover glass; and equipped with a bypass diode, which is placed beside the photovoltaic cell in most technologies.

A photovoltaic network is an assembly or layout of photovoltaic cells that are tiled side-by-side. An optimal network is therefore constructed from elementary shapes that are able to tessellate (squares, rectangles, hexagons, etc.) in order to prevent space from being wasted and to obtain the best packing factors, or in other words the best ratios of the area of the photovoltaic cells to the area of the supporting structure, or the most compact layout.

Raw cells, i.e. circular cells, are the most economical because they do not generate cutting losses or waste, but the layout thereof is far from optimal and leaves many empty zones in the panel or layout or assembly, leading to additional costs being incurred in the production of the extra or larger panels required for a given power.

The networks or layouts generally chosen by present-day manufacturers often use square cells 1, as illustrated in FIG. 1, or half-square cells 2, as illustrated in FIG. 2 (for reasons to do with the manufacturing process, but the principle remains the same), to form the network, and imply the loss of a fair amount of the (originally circular) cell 3 initially produced.

For square photovoltaic cells 1 or half-square photovoltaic cells 2, 63% of the circular raw cell 3 is used and thus 37% thereof is lost; however, the packing factor obtained is 100%.

These cells are used when the bypass diode is integrated. In the case of use of discrete diodes, which are placed beside the cells, the solution is to use a square or half-square shape with a bevelled corner.

In the end, the compromise made is generally to use square cells 4 or half-square cells 5 with bevelled corners, as illustrated in FIGS. 3 and 4, respectively.

Such photovoltaic cells 4, 5 allow loss of the circular raw cell 3 to be limited, typically to a loss of 10 to 18%, and allow a layout with a good packing factor, typically about 83 to 94%, to be obtained. The portions left free by the bevelled corners are generally used to accommodate bypass diodes, which make it possible to prevent cells that are not exposed to light or that have malfunctioned from behaving as load cells and dissipating the power generated by other cells.

The bypass diodes make it possible to avoid this and are connected in parallel to each cell.

It is also known to use moon-shaped cells 6 or half-moon-shaped cells 7 (as shown in FIGS. 5 and 6, respectively) which allow a larger portion of the circular raw cell 3 to be used.

Such photovoltaic cells allow loss of the circular raw cell to be limited, typically to a loss of 2%, but tile with a limited packing factor, typically about 91%. The portions left free are generally used to accommodate bypass diodes.

### SUMMARY OF THE INVENTION

One aim of the invention is to optimize not only the losses made cutting raw cells or wafers but also the compactness with which the cells obtained may be tiled.

Thus, according to one aspect of the invention, what is proposed is a network of photovoltaic cells that are aligned in at least one row so that, in one row of cells, the base of a cell is alternately on one edge of the row then on the other edge of the row, the photovoltaic cells being the shape of a half regular hexagon the environs of the vertices of which are truncated so that the truncation corresponds to a section of a semicircle the base and diameter of which is superposed and centred on the base of the half-hexagon, the base of the half-hexagon being comprised between 1 and

$$\frac{2}{\sqrt{3}}$$

times the diameter of the semicircle.

Such a layout of such a cell optimizes not only the losses made cutting raw cells or wafers but also the compactness with which the cells obtained may be tiled.

Specifically, such a layout allows loss of the circular raw cell to be limited, typically to a loss of 3%, and allows a layout with a good packing factor, typically about 95%, to be obtained. The portions left free are generally used to accommodate bypass diodes.

Such a photovoltaic-cell shape makes it possible to optimize not only the losses made cutting raw cells or wafers of circular shape but also the compactness with which the cells obtained may be tiled.

Furthermore, a single photovoltaic-cell design is enough to produce such a network, thereby limiting costs.

According to one embodiment, the base of the half-hexagon equals 161.1 mm for a substrate of 150 mm diameter.

This value is optimal.

In one embodiment, the diameter of the semicircle is 100 mm or 150 mm.

Such a diameter corresponds to a diameter that is conventional for raw photovoltaic cells or wafers and that is therefore accessible at limited cost.

In one embodiment, the network comprises bypass diodes placed between cells of the network in portions corresponding to said truncated portions.

The truncated corners therefore allow both the utilization of the wafer to be increased and the bypass diodes to be accommodated.

For example, the arrangement of the bypass diodes forms a regular pattern.

### BRIEF DESCRIPTION OF THE DRAWINGS

The invention will be better understood on studying a few embodiments, which are described by way of completely nonlimiting example and illustrated by the appended drawings, in which:

FIG. 1 schematically illustrates the cutting of a square photovoltaic cell in a raw photovoltaic cell, according to the prior art;

FIG. 2 schematically illustrates the cutting of two half-square photovoltaic cells in a raw photovoltaic cell, according to the prior art;

FIG. 3 schematically illustrates the cutting of a square photovoltaic cell with bevelled corners in a raw photovoltaic cell, according to the prior art;

FIG. 4 schematically illustrates the cutting of two half-square photovoltaic cells with bevelled corners in a raw photovoltaic cell, according to the prior art;

FIG. 5 schematically illustrates the cutting of a moon-shaped photovoltaic cell in a raw photovoltaic cell, according to the prior art;

FIG. 6 schematically illustrates the cutting of two half-moon-shaped photovoltaic cells in a raw photovoltaic cell, according to the prior art;

FIG. 7 schematically illustrates the cutting of two photovoltaic cells in a raw photovoltaic cell, according to one aspect of the invention;

FIG. 8 schematically illustrates the limits of truncation half-hexagons of two photovoltaic cells with respect to a raw photovoltaic cell, according to one aspect of the invention; and

FIG. 9 schematically illustrates a network or layout of photovoltaic cells, according to one aspect of the invention.

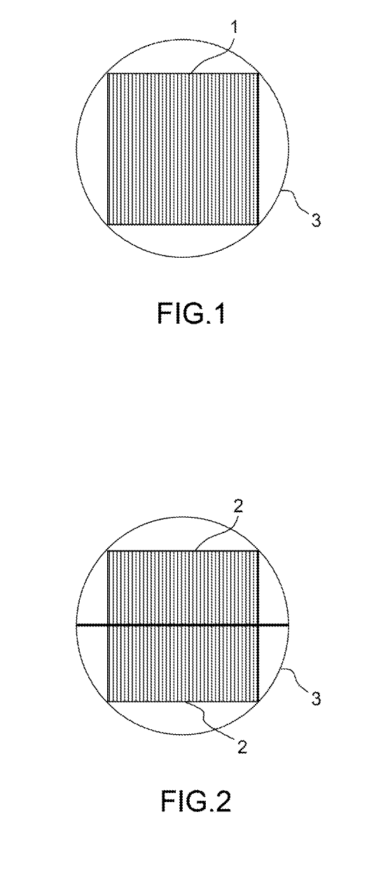

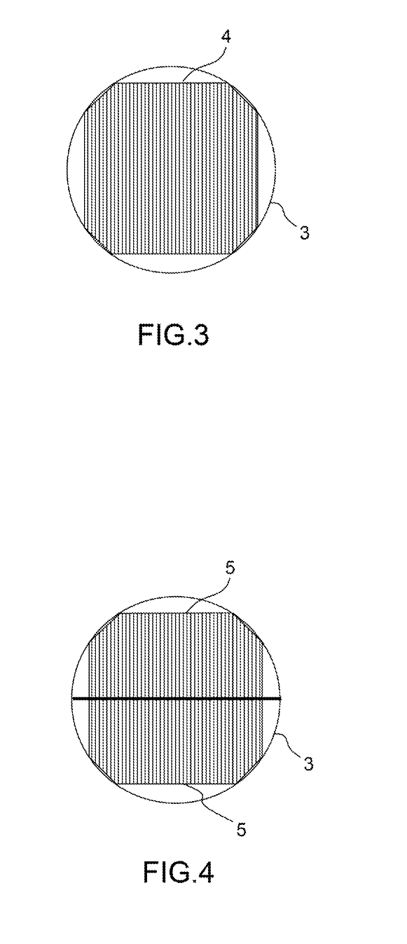

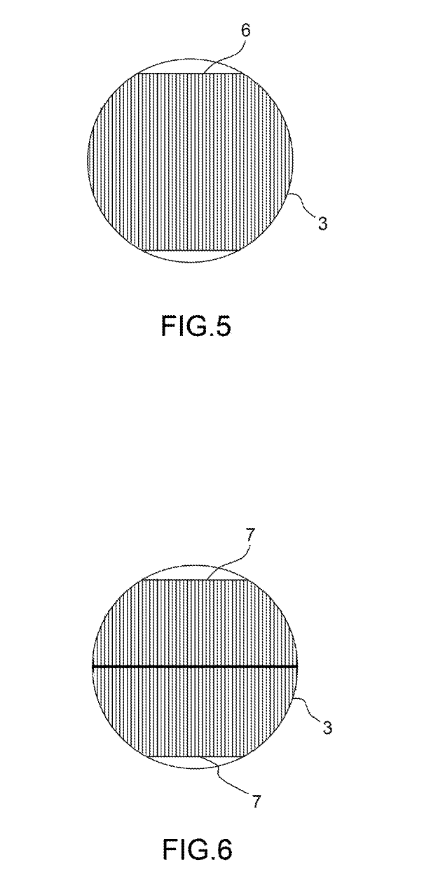

### DETAILED DESCRIPTION

In the various figures, elements referenced with identical references are identical.

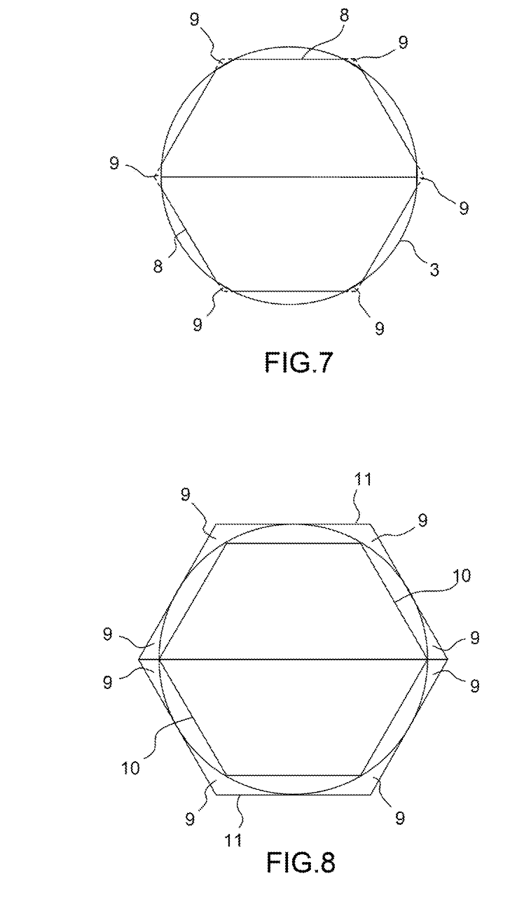

FIG. 7 shows a circular raw cell 3 in which two photovoltaic cells 8 according to one aspect of the invention have been cut. The circular raw photovoltaic cell 3 has been cut with two half-hexagons such that the base of one half-hexagon is aligned and centred on a diameter of the circular raw photovoltaic cell 3, the base of the half-hexagon being comprised between 1 times and

$$\frac{2}{\sqrt{3}}$$

times the diameter of the circular raw photovoltaic cell 3. Thus, in the end, each of the two photovoltaic cells according to one aspect of the invention is the shape of a half regular hexagon the environs of the vertices of which are truncated so that the truncation 9 corresponds to a section of a semicircle the base and diameter of which is superposed and centred on the base of the half-hexagon, the base of the half-hexagon being comprised between 1 and

$$\frac{2}{\sqrt{3}}$$

times the diameter of the semicircle of the circular raw photovoltaic cell 3.

FIG. 8 illustrates half-hexagons 10 and 11 the bases of which measure the diameter and

$$\frac{2}{\sqrt{3}}$$

times the diameter or the circular raw photovoltaic cell 3, respectively.

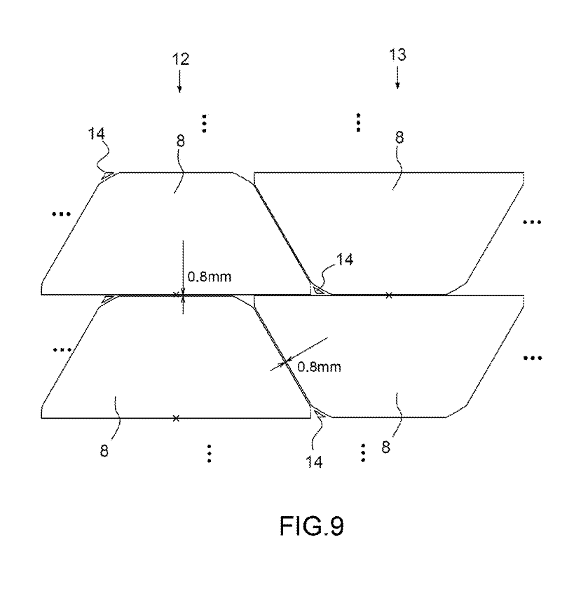

FIG. 9 schematically shows a small section of a network or layout of cells 8 according to the invention. This figure shows two respective columns 12 and 13 of adjacent aligned cells respectively containing only two cells 8. Typically, the distance separating two cells 8 of the network is 0.8 mm, as shown in FIG. 9. For two consecutive adjacent columns 12 and 13, the bases of the cells of one column 12 are placed at the bottom of the cells 8 and conversely at the top of the cells 8 in the adjacent column 13, and so on.

The spaces corresponding to the truncations 9 allow bypass diodes 14 to be accommodated.

In the present case, the bypass diodes 14 are accommodated in the truncated portion 9 of a vertex so that their arrangement forms a regular pattern.

In the example illustrated in FIG. 9, the bypass diodes are accommodated in the truncated portion of a vertex not belonging to the base of the half-hexagon for one column, and, for an adjacent column, in the other vertex not belonging to the base of the half-hexagon, and so on.

The rounded-vertex half-hexagon geometry of these photovoltaic cells 8 makes it possible to obtain an associated network or layout that maximizes the size of the cell with respect to the circular raw cell while also ensuring the associated network has an excellent packing factor.

The invention consists in cutting the photovoltaic cell into round-cornered half-hexagons in order to optimize the packing factor of the layout or network of cells and the cutting of the cell and makes it possible not only to benefit from the ability to cut to the edges of the wafer, which in any case are passivated, but also to permit a small loss of area for installation of a bypass diode.

1. A network of photovoltaic cells that are aligned in at least one row so that, in one row of cells, the base of a cell is alternately on one edge of the row then on the other edge of the row, the photovoltaic cells being the shape of a half regular hexagon the environs of the vertices of which are truncated so that the truncation corresponds to a section of a semicircle the base and diameter of which is superposed and centred on the base of the half-hexagon, the base of the half-hexagon being comprised between 1 and
$$\frac{2}{\sqrt{3}}$$
times the diameter of the semicircle.

2. The network of photovoltaic cells according to claim 1, wherein the base of the half-hexagon equals 161.1 mm for a diameter of 150 mm.

3. The network of photovoltaic cells according to claim 1, wherein the diameter of the semicircle is 100 mm or 150 mm.

4. The network of photovoltaic cells according to claim 1, comprising bypass diodes placed between cells of the network in portions corresponding to said truncated portions.

5. The network of photovoltaic cells according to claim 4, wherein the arrangement of the bypass diodes forms a regular pattern.
